(19) United States
(12) Patent Application Publication
(10) Pub. No.: US 2002/0172298 A1
(43) Pub. Date: Nov. 21, 2002

(54) Radio frequency receiver

(76) Inventors: Rachid Waffaoui El, Eindhoven (NL); Jan Van Sinderen, Eindhoven (NL)

Correspondence Address: U.S. Philips Corporation, 580 White Plains Road, Tarrytown, NY, 10591, US

(21) Appl. No.: 10/114,506

(22) Filed: Apr. 2, 2002

(30) Foreign Application Priority Data
Apr. 5, 2001 (EP) 01201254.8

(51) Int. Cl. H03K 9/00

(52) U.S. Cl. 375/316

(57) ABSTRACT

A radio frequency receiver with quadrature mixing and means for analog to digital converting the I and Q signals obtained from the quadrature mixing. To improve the image suppression the analog to digital converting means are multiplexed between the channels of the I and Q signals.

This invention relates to a radio frequency receiver comprising I and Q channels with I and Q mixing stages respectively for quadrature mixing a radio frequency input signal with 90° phase shifted local oscillator signals, and I and Q selectivity filters for filtering the output signals of said I and Q mixing stages respectively, said receiver further comprising analog to digital converter means for analog to digital converting the analog signals of said two channels. Such receiver is known from U.S. Pat. No. 5,159,710.

The specifications for the selectivity of radio frequency receivers, especially transceivers, are becoming more severe. Thus the receiver architecture should be designed with a maximum image suppression but still at low cost. The image suppression can be improved by mixing the received signal to a sufficiently high intermediate frequency, so that the image is relatively far away from the desired signal and the radio frequency preselection provides a high degree of image suppression. However in receivers with a low intermediate frequency and especially in receivers with direct (=zero-IF) conversion, the radio frequency preselection is not effective for the image suppression and in those cases the image suppression is preferably realized by quadrature mixing. The radio frequency signal is applied to two mixers, which receive local oscillations one of which is shifted by 90° with respect to the other. When the two mixer output signals are applied through matched channels, comprising inter alia anti-aliasing filters, and the signal in one channel is rotated by 90° with respect to the signal in the other channel, then the outputs of the two channels can be combined so that the desired signal is added while the undesired image signal is suppressed.

In the prior art receivers of the above described kind each of the signals of the two channels is digitized in an analog to digital converter and the two digital signals so obtained are combined to suppress the reception of undesired image frequencies.

However, the image suppression is limited when the two channels are not perfectly matched. This means that any inequalities in gain and phase shift between the two channels, especially between the two AD converters, deteriorates the image suppression.

Therefore, it is a first object of the present invention to substantially reduce the mismatch between the two channels and therefore the radio frequency receiver of the present invention is characterized in that the analog to digital converting means comprise an analog to digital-converter which is multiplexed between the two channels to operate sequentially for converting the analog signals of said two channels. By this measure the same converter is used, sequentially, for converting both the I- and Q-signals, so that the AD-conversion cannot be any more a source of IQ-mismatch.

Since, in this case, the AD conversion is done in series, the maximum sampling rate is limited and this limitation of the sampling rate puts high requirements on the IF selectivity. It is a further object of the invention to take advantage of the increasing speed of current and future CMOS AD converters and therefore the radio frequency receiver of the invention is characterized by two analog to digital converters, each of which is multiplexed between the two channels and in that one of the two analog to digital converters is operative to convert the analog signal of one of the two channels when the other of the two analog to digital converters is operative to convert the analog signal of the other of the two channels and vice versa. By this measure the two AD converters operate always in parallel so that the maximum allowable sampling rate is substantially increased.

Preferably an AD converter may be preceded by a track and hold amplifier, which tracks the analog input signal during a track period and which then holds the sampling level, obtained at the end of the track period, during a hold period for evaluation by the DA converter. This gives the DA converter ample time to evaluate the sampling level and to convert this level to the corresponding digital value. The track and hold amplifier therefore separates the sampling operation from the digitizing operation. It is a still further object of the invention to provide a radio frequency receiver with track and hold means preceding the analog to digital converter means, which is characterized in that the track and hold means are, together with the analog to digital converter means, multiplexed between the two channels. This measure further improves the IQ-matching because any gain and phase shift inequalities in the track and hold amplifiers are also multiplexed to outside the frequency band of interest. In such radio frequency receiver, wherein the track and hold means preceding the analog to digital converter means, comprise a switch for applying the analog signal to be converted to a capacitor during a track mode and for holding the signal voltage across the capacitor during a hold mode, may advantageously be characterized in that the track and hold switch is also used to multiplex the analog to digital converter means between the two channels. In this way a substantial simplification of the circuitry is obtained.

More specifically, the radio frequency receiver of the present invention may be characterized in that said switch has four phases, a first track phase during which the analog signal of the first channel is applied to the hold capacitor, a first hold phase in which the analog signal of the first channel is disconnected from the hold capacitor and said capacitor holds the analog signal level of the first channel for analog to digital conversion, a second track phase in which the analog signal of the second channel is applied to the hold capacitor and a second hold phase in which the analog signal of the second channel is disconnected from the hold capacitor and said capacitor holds the analog signal level of the second channel for analog to digital conversion.

The invention will be further explained with reference to the attached figures. Herein shows:

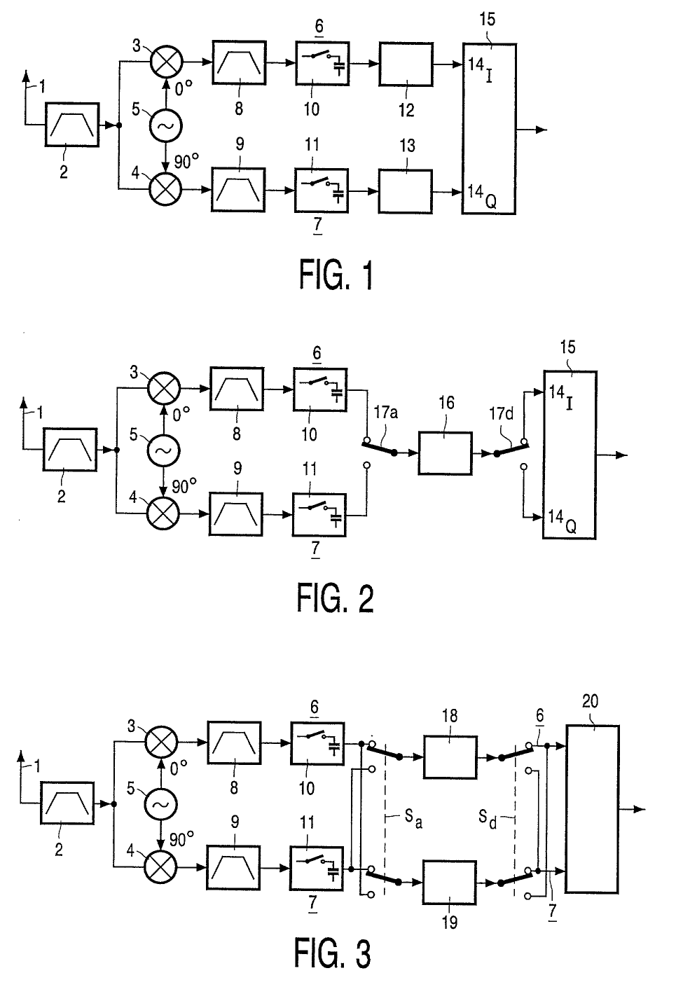

FIG. 1 a prior art radio frequency receiver,

FIG. 2, 3, and 4 different embodiments of a radio frequency receiver in accordance with the invention and

FIG. 5 a combined multiplex and track and hold arrangement for use in a radio frequency receiver in accordance with the invention.

The prior art radio frequency receiver of FIG. 1 comprises an antenna 1 and a radio frequency selectivity filter 2 the output of which is applied to two mixers 3 and 4. These mixers each have a local oscillator input which is connected to a local oscillator 5. The mixer 4 receives a local oscillator signal which is 90° phase-shifted with respect to the local oscillator signal supplied to the mixer 3. I- and Q-channels 6 and 7, connected to the outputs of the mixers 3 and 4 respectively, may each comprise an intermediate frequency (IF) selectivity filter 8-9, an AGC-stage (not shown), a track and hold amplifier 10-11 and an AD converter 12-13. The AD converters deliver digital I and Q signals to input terminals 14_{I} and 14_{Q} of a digital processor 15 in which the IF-demodulation, the derotation and the combination of the two signals is carried out. This combination results in a demodulated digital signal in which the desired signals of the two channels are added and in which the undesired image signals of the two channels cancel against each other. This cancellation is better the better the I- and Q-channels match with respect to their gain and phase shift. A major cause of inequalities in gain and phase are the AD converters 12 and 13.

In the radio frequency receiver of FIG. 2 elements corresponding to those of FIG. 1 have the same reference numerals. In this arrangement the two AD converters 12 and 13 of FIG. 1 are replaced by a single AD converter 16. An analog switch 17a switches the input of this AD converter at a sufficiently high rate between the outputs of the two track and hold amplifiers 10 and 11. The output of the AD converter 16 is connected to a digital switch 17_{d} which runs synchronously with the analog switch 17ₐ and which switches the digital output of the AD converter 16 between the inputs 14_{I} and 14_{Q} of the digital processor 15. Because the same AD converter is used for both channels 6 and 7, the IQ-mismatch caused by the inequalities of the two AD converters of FIG. 1, is avoided in the arrangement of FIG. 2.

When Tₜ is the required track time of the track and hold amplifiers to achieve a specific linearity and T_{c} is the time needed by the AD converter to perform a conversion, then, in the arrangement of FIG. 2, the sample rate Fₛ is limited to a maximum of 1/(Tₜ+2T_{c}). This limitation of the sample rate puts high requirements on the IF-selectivity. This means that higher order, for example not integratable LC- or SAW-filters are required.

An improvement is obtained with the radio frequency receiver of FIG. 3, in which again the elements corresponding to those of FIGS. 1 and 2 have the same reference numerals. This receiver comprises two AD converters 18 and 19 which are connected to the track and hold amplifiers 10 and 11 through an analog switch-set Sₐ and which are connected to a digital processor 20 through a digital switch-set S_{d}. The two switch-sets run synchronously at a multiplex frequency Fₘ, so that during one half cycle of this frequency the AD converter 18 is connected into the I-channel 6 and the AD converter 19 into the Q-channel 7. During the other half cycle of the multiplex frequency Fₘ, the AD converter 18 is connected into the Q-channel 7 and the AD converter 19 into the I-channel 6.

Because, in this arrangement, the two AD converters operate in parallel the sampling rate can be substantially higher. With this arrangement the maximum sampling rate is 1/(Tₜ+T_{c}), while the preferred multiplex frequency Fₘ=½ Fₛ, so that during each half cycle of the multiplex frequency one complete sample and hold operation is performed.

In contradistinction with the arrangement of FIG. 2, inequalities in gain and phase between the two AD converters of FIG. 3 can exist. However, due to the multiplex operation, these inequalities are modulated to a frequency band around the frequency Fₘ−Fᵢ, where Fᵢ is the intermediate frequency. Therefore, by choosing the multiplex frequency sufficiently high, the distortion caused by these inequalities can be transferred to outside the band of interest.

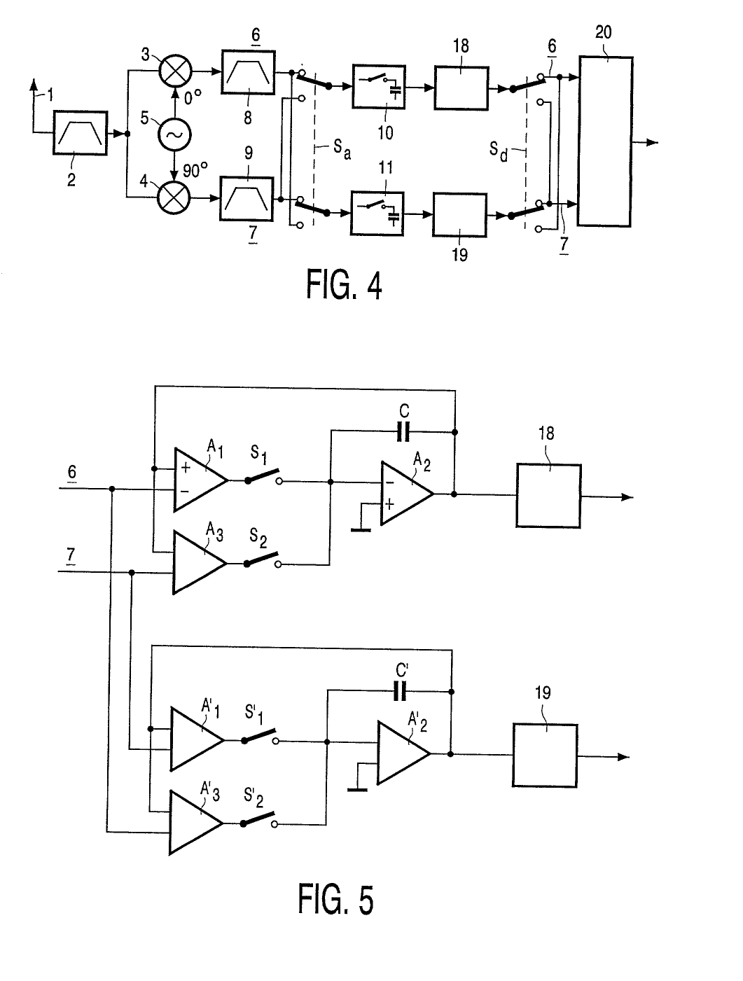

A further improvement is illustrated with reference to FIG. 4. In the arrangement of this figure the two sample and hold arrangements are, together with the AD converters, included in the multiplex operation. The output signals of the IF-selectivity filters 8 and 9 are multiplexed by the analog switch-set Sₐ and the two multiplexed signals are applied to the two sample and hold amplifiers 10 and 11. This has the advantage that any distortion caused by the inequalities between the track and hold amplifiers are, together with the distortion caused by the inequalities of the AD converters 18 and 19, transferred to outside the frequency band of interest. Another advantage is that the multiplex switches and the track and hold switches may conveniently be combined. This is illustrated with reference to FIG. 5.

In this figure the analog input signal from the I-channel 6 is applied to the inverting input of a first operational amplifier A1 whose output is connected, through a switch S₁, to the inverting input of a second operational amplifier A₂. The output of the second operational amplifier is fed back to the inverting input of this amplifier through a hold capacitor C and directly to the non-inverting input of the amplifier A₁. The non-inverting input of amplifier A₂ is at a reference potential. The feedback from the output of amplifier A₂ to the non-inverting input of amplifier A₁ with the fact hat the total loop gain is very large improves the linearity and the matching with the other track and hold stage during the track mode. Capacitor C is used to perform the hold function when the switch S₁ is open and the voltage of this capacitor is used to drive the AD converter 18. A similar track and hold amplifier comprising the amplifiers A₁′ and A₂′, a switch S₁′ and a hold capacitor C′ is provided for simultaneously handling the signal from the Q-channel 7 and for driving the AD converter 19.

For the purpose of multiplexing, the arrangement of FIG. 5 comprises a third amplifier A₃ and a switch S2 which constitute a second loop with the amplifier A₂ and the capacitor C, similar to the loop A₁, S₁, A₂, C. This second loop tracks and holds the signal of the Q-channel for application to the AD converter 18. Similarly a fourth amplifier A₃′ and a fourth switch S₂′ constitute a loop with the amplifier A₂′ and the capacitor C′ for handling the signal of the I-channel for application to the DA converter 19. From this it may be clear that the amplifier A₂ and the hold capacitor C are common to both loops A₁, S₁, A₂, C and A₃, S₂, A₂, C. Similar applies to the amplifier A₂′ and its hold capacitor C′.

In the arrangement of FIG. 5 the switches are driven as follows:

During a first period the switches S₁ and S₁′ are closed and the switches S₂ and S₂′ are open. During this period the amplifiers A₁ and A₂ form a closed loop which tracks the I-signal into the capacitor C. and the amplifiers A₁′ and A₂′ form a closed loop which tracks the Q signal into the capacitor C′.

During a second period all switches are open and during this hold period the voltage of capacitor C is hold and evaluated by the AD converter 18 and the voltage of capacitor C′ is hold and evaluated by the AD converter 19.

During a third period the switches S₂ and S₂′ are closed while the switches SI and S₁′ are open. Now the amplifiers A₃ and A₂ form a closed loop which tracks the Q signal into capacitor C and the amplifiers A₃′ and A₂′ form a closed loop which tracks the I signal into capacitor C′.

During a fourth period all switches are again open and during this period the voltage of capacitor C is hold and evaluated by AD converter 18 and the voltage of capacitor C′ is hold and evaluated by AD converter 19.

In practice, each of the analog switches S₁, S₂, S₁′ and S₂′ may comprise the parallel arrangement of a PMOS transistor and a NMOS transistor, which arrangement is switched by a symmetrical switching signal.

In the above described arrangements it has been assumed that during each half cycle of the multiplex frequency Fₘ one complete track and hold operation is performed, so that the multiplex frequency Fₘ is one half the sampling rate Fₛ. Theoretically each half cycle of the multiplex frequency may comprise more than one track and hold cycle, so that the multiplex frequency equals Fₛ/2n with n>1. However, because the sample rate is usually determined by other factors, such as the speed of the DA converters, this would only mean that the multiplex frequency is reduced, which is usually undesirable.

1. A radio frequency receiver comprising I and Q channels (6,7) with I and Q mixing stages (3,4) respectively for quadrature mixing a radio frequency input signal with 90° phase shifted local oscillator signals, and I and Q selectivity filters (8,9) for filtering the output signals of said I and Q mixing stages respectively, said receiver further comprising analog to digital converter means for analog to digital converting the analog signals of said two channels, characterized in that the analog to digital converting means comprise an analog to digital-converter (16) which is multiplexed between the two channels (6,7) to operate sequentially for converting the analog signals of said two channels.

2. A radio frequency receiver as claimed in claim 1, characterized by two analog to digital converters (18,19), each of which is multiplexed between the two channels (6,7) and in that one of the two analog to digital converters is operative to convert the analog signal of one of the two channels when the other of the two analog to digital converters is operative to convert the analog signal of the other of the two channels and vice versa.

3. A radio frequency receiver as claimed in claim 1 or 2, with track and hold means (10,11) preceding the analog to digital converter means (18,19), characterized in that the track and hold means are, together with the analog to digital converter means, multiplexed between the two channels (6,7).

4. A radio frequency receiver as claimed in claim 3 wherein the track and hold means (10,11) preceding the analog to digital converter means, comprise a switch for applying the analog signal to be converted to a capacitor (C,C′) during a track mode and for holding the signal voltage across the capacitor during a hold mode, characterized in that the track and hold switch (S₁,S₂,S₁′,S₂′) is also used to multiplex the analog to digital converter means (18,19) between the two channels (6,7).

5. A radio frequency receiver as claimed in claim 4 characterized in that said switch (S₁,S₂) has four phases, a first track phase during which the analog signal of the first channel (6) is applied to the hold capacitor (C), a first hold phase in which the analog signal of the first channel (6) is disconnected from the hold capacitor (C) and said capacitor holds the analog signal level of the first channel (6) for analog to digital conversion, a second track phase in which the analog signal of the second channel (7) is applied to the hold capacitor (C) and a second hold phase in which the analog signal of the second channel is disconnected from the hold capacitor and said capacitor holds the analog signal level of the second channel (7) for analog to digital conversion.
